(19) United States
(12) Patent Application Publication
(10) Pub. No.: US 2010/0163090 A1
(43) Pub. Date: Jul. 1, 2010

(54) THERMOELECTRIC DEVICE AND FABRICATION METHOD THEREOF, CHIP STACK STRUCTURE, AND CHIP PACKAGE STRUCTURE

(75) Inventors: Chun-Kai Liu, Taipei City (TW); Shu-Ming Chang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/640,013

(22) Filed: Dec. 17, 2009

(30) Foreign Application Priority Data
Dec. 31, 2008 (TW) 97151887

(51) Int. Cl. H01L 35/28; H01L 21/50; H01L 35/34

(52) U.S. Cl. 136/224; 438/55; 136/201; 257/E21.499

(57) ABSTRACT

A thermoelectric device including a first substrate, a plurality of conductive vias, a second substrate, a thermoelectric couple module, a first insulation layer, and a second insulation layer is provided. The first substrate has a first surface and a second surface opposite to each other. The conductive vias running through the first substrate respectively connect the first and the second surface. The second substrate faces the second surface of the first substrate. The thermoelectric couple module including a plurality of thermoelectric couples connected with each other in series is disposed between the first and the second substrate and coupled to the conductive vias. The first insulation layer is disposed between the thermoelectric couple module and the first substrate. The second insulation layer is disposed between the thermoelectric couple module and the second substrate.

### CROSS-REFERENCE TO RELATED APPLICATION

This application claims the priority benefit of Taiwan application serial no. 97151887, filed on Dec. 31, 2008. The entirety of the above-mentioned patent application is hereby incorporated by reference herein and made a part of specification.

### BACKGROUND

1. Technical Field

The disclosure generally relates to a heat dissipation device and a fabrication method thereof and a chip package structure and a chip stack structure having the heat dissipation device, and more particularly, to a thermoelectric device and a fabrication method thereof and a chip package structure and a chip stack structure having the thermoelectric device.

2. Description of Related Art

Thermoelectric devices made of thermoelectric semiconductor materials are broadly applied to cooling or heating apparatuses because they do not need any liquid or gas as coolant and have such advantages as non-stop operation, contamination-free, moving-part-free, noise-free, long lifespan, small volume, and light weight, etc.

Generally speaking, a thermoelectric device includes an upper substrate, a lower substrate, and a plurality of N type semiconductor members and P type semiconductor members which are disposed between the upper substrate and the lower substrate and arranged regularly. The N type semiconductor members and the P type semiconductor members are connected with each other in series to form a plurality of thermoelectric couples and a plurality of power lines are electrically connected to the thermoelectric couples. When a current passes through the thermoelectric couples, an end of the thermoelectric device absorbs heat (becomes a cold end) due to the Peltier effect, and the other end of the thermoelectric device releases heat (becomes a hot end), and the positions of the cold end and hot end are changed if the current is reversed. The thermoelectric device can be applied to a cooling or heating apparatus based on the phenomenon described above. However, because the power lines will interfere with a sealed structure, it is difficult to integrate the thermoelectric device into a chip package structure.

Additionally, in the conventional technique, a plurality of metal pads may be disposed on a surface of a carrier in the chip package structure, and the thermoelectric device may be connected to the metal pads through wire bonding. However, these metal pads take up the limited surface of the carrier, and the bonding wires increase the thickness of the chip package structure.

### SUMMARY

Accordingly, the disclosure is directed to a thermoelectric device which can be easily integrated into a chip package structure or a chip stack structure.

The disclosure is directed to chip package structure having a thermoelectric device.

The disclosure is directed to a chip stack structure having a thermoelectric device.

The disclosure is directed to a fabrication method of a thermoelectric device, wherein the thermoelectric device can be easily integrated into a chip package structure or a chip stack structure.

The disclosure provides a thermoelectric device including a first substrate, a plurality of conductive vias, a second substrate, a thermoelectric couple module, a first insulation layer, a second insulation layer. The first substrate has a first surface and a second surface opposite to the first surface. The conductive vias run through the first substrate and respectively connect the first surface and the second surface. The second substrate is disposed opposite to the first substrate, wherein the second surface of the first substrate faces the second substrate. The thermoelectric couple module including a plurality of thermoelectric couples connected with each other in series is disposed between the first substrate and the second substrate and is coupled to the conductive vias. The first insulation layer is disposed between the thermoelectric couple module and the first substrate. The second insulation layer is disposed between the thermoelectric couple module and the second substrate.

The disclosure provides a chip package structure including a carrier substrate, a thermoelectric device, a chip, and a heat sink. The thermoelectric device is disposed on the carrier substrate. The thermoelectric device includes a first substrate, a plurality of conductive vias, a second substrate, a thermoelectric couple module, a first insulation layer, and a second insulation layer. The first substrate has a first surface and a second surface opposite to the first surface. The conductive vias run through the first substrate and respectively connect the first surface and the second surface. The second substrate is disposed opposite to the first substrate, wherein the second surface of the first substrate faces the second substrate. The thermoelectric couple module including a plurality of thermoelectric couples connected with each other in series is disposed between the first substrate and the second substrate and is coupled to the conductive vias. The first insulation layer is disposed between the thermoelectric couple module and the first substrate. The second insulation layer is disposed between the thermoelectric couple module and the second substrate. The chip is disposed between the thermoelectric device and the carrier substrate, and the chip and the thermoelectric device are respectively coupled to the carrier substrate. The heat sink is disposed on the second substrate.

The disclosure provides a chip stack structure including a plurality of chips stacked together and a thermoelectric device. The thermoelectric device is disposed between any adjacent two of the chips. The thermoelectric device includes a first substrate, a plurality of conductive vias, a second substrate, a thermoelectric couple module, a first insulation layer, and a second insulation layer. The first substrate has a first surface and a second surface opposite to the first surface. The conductive vias run through the first substrate and respectively connect the first surface and the second surface. The second substrate is disposed opposite to the first substrate, wherein the second surface of the first substrate faces the second substrate. The thermoelectric couple module including a plurality of thermoelectric couples connected with each other in series is disposed between the first substrate and the second substrate and is coupled to the conductive vias. The first insulation layer is disposed between the thermoelectric couple module and the first substrate. The second insulation layer is disposed between the thermoelectric couple module and the second substrate.

The disclosure provides a fabrication method of a thermoelectric device. First, a first substrate, a plurality of conductive vias, and a first insulation layer are provided, wherein the first substrate has a first surface and a second surface opposite to the first surface, the conductive vias run through the first substrate and respectively connect the first surface and the second surface, the first insulation layer is disposed on the second surface. Then, a first electrode pattern layer is formed on the first insulation layer, and the first electrode pattern layer is coupled to the conductive vias. Next, a plurality of first thermoelectric pillars is formed on the first electrode pattern layer, and the first thermoelectric pillars are coupled to the first electrode pattern layer, wherein the material of the first thermoelectric pillars includes a first type thermoelectric material. After that, a second substrate and a second insulation layer are provided, wherein the second insulation layer is disposed on the second substrate. Thereafter, a second electrode pattern layer is formed on the second insulation layer. Next, a plurality of second thermoelectric pillars is formed on the second electrode pattern layer, and the second thermoelectric pillars are coupled to the second electrode pattern layer, wherein the material of the second thermoelectric pillars includes a second type thermoelectric material. Thereafter, the second substrate is disposed on the first substrate to locate the first thermoelectric pillars and the second thermoelectric pillars between the first electrode pattern layer and the second electrode pattern layer, wherein the first thermoelectric pillars and the second thermoelectric pillars are connected with each other in series through the first electrode pattern layer and the second electrode pattern layer to form a thermoelectric couple module.

As described above, in the disclosure, a thermoelectric device is coupled to an external power source through conductive vias. Thus, the thermoelectric device in the disclosure does not need to be coupled to the external power source through any power line or bonding wire (as in the conventional technique). Accordingly, in the disclosure the volume of the thermoelectric device is reduced and the thermoelectric device can be easily integrated into a chip package structure or a chip stack structure.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a cross-sectional view of a thermoelectric device according to an embodiment of the disclosure.

FIG. 2 is a cross-sectional view of a chip package structure according to an embodiment of the disclosure.

FIG. 3 is a cross-sectional view of a chip package structure according to an embodiment of the disclosure.

FIG. 4 is a cross-sectional view of a chip package structure according to an embodiment of the disclosure.

FIG. 5 is a cross-sectional view of a variation of the chip package structure in FIG. 4.

FIG. 6 is a cross-sectional view of a chip stack structure according to an embodiment of the disclosure.

FIG. 7 is a cross-sectional view of a variation of the chip stack structure in FIG. 6.

FIGS. 8A-8F are cross-sectional views illustrating a fabrication process of a thermoelectric device according to an embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

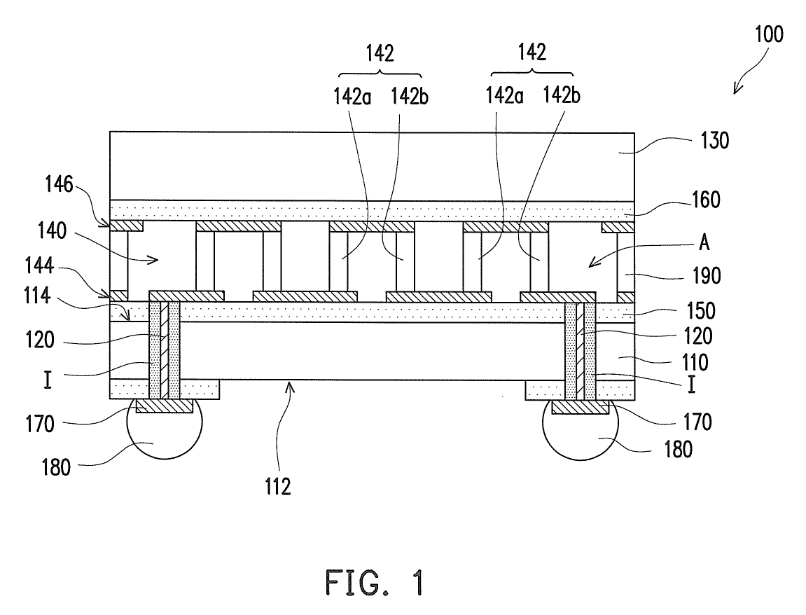

FIG. 1 is a cross-sectional view of a thermoelectric device according to an embodiment of the disclosure. Referring to FIG. 1, in the present embodiment, the thermoelectric device 100 includes a first substrate 110, a plurality of conductive vias 120, a second substrate 130, a thermoelectric couple module 140, a first insulation layer 150, and a second insulation layer 160.

In the present embodiment, the first substrate 110 may be a metal substrate, a silicon substrate, or other suitable substrate, wherein the silicon substrate may be a chip. The first substrate 110 has a first surface 112 and a second surface 114 opposite to the first surface 112. The conductive vias 120 run through the first substrate 110 and respectively connect the first surface 112 and the second surface 114.

In the present embodiment, when the first substrate 110 is a non-insulated substrate (for example, a metal substrate or a silicon substrate), a plurality of insulation materials I may be disposed respectively between the conductive vias 120 and the first substrate 110 to avoid short circuit between the first substrate 110 and the conductive vias 120. As described above, the first substrate 110 may be made of a material with high heat conductivity, such as metal. Accordingly, the thermoelectric device 100 in the present embodiment has a good cooling (or heating) effect.

In the present embodiment, the thermoelectric device 100 is coupled to an external power source through a plurality of metal pads 170 and a plurality of conductive bumps 180. The metal pads 170 are disposed on the first surface 112 of the first substrate 110 and respectively connect the conductive vias 120 and the conductive bumps 180 disposed thereon.

In the present embodiment, the second substrate 130 may be a metal substrate, a silicon substrate, or other suitable substrate, wherein the silicon substrate may be a chip. The second substrate 130 and the first substrate 110 are disposed opposite to each other, wherein the second surface 114 of the first substrate 110 faces the second substrate 130. The thermoelectric couple module 140 is disposed between the first substrate 110 and the second substrate 130 and is coupled to the conductive vias 120. The first insulation layer 150 is disposed between the thermoelectric couple module 140 and the first substrate 110. The second insulation layer 160 is disposed between the thermoelectric couple module 140 and the second substrate 130.

In the present embodiment, the thermoelectric couple module 140 includes a plurality of thermoelectric couples 142 connected with each other in series. To be specific, each of the thermoelectric couples 142 has a first thermoelectric pillar 142a and a second thermoelectric pillar 142b, wherein the first thermoelectric pillars 142a in the thermoelectric couples 142 are coupled to the second thermoelectric pillars 142b through a second electrode pattern layer 146 disposed on the second insulation layer 160. In the present embodiment, a plurality of solders (not shown) may be disposed between the first thermoelectric pillars 142a and the second electrode pattern layer 146 to electrically connect the first thermoelectric pillars 142a and the second electrode pattern layer 146.

Additionally, in the present embodiment, the thermoelectric couples 142 are connected with each other in series through a first electrode pattern layer 144 disposed on the first insulation layer 150 and coupled to the conductive vias 120 through the first electrode pattern layer 144. In the present embodiment, a plurality of solders (not shown) may be disposed between the second thermoelectric pillars 142b and the first electrode pattern layer 144 to electrically connect the second thermoelectric pillars 142b and the first electrode pattern layer 144. The material of the first thermoelectric pillars 142a includes a first type thermoelectric material, and the material of the second thermoelectric pillars 142b includes a second type thermoelectric material, wherein the first type thermoelectric material or the second type thermoelectric material may be a N-type semiconductor material or a P-type semiconductor material.

As described above, because the thermoelectric couple module 140 is coupled to an external power source via the conductive vias 120, the thermoelectric device 100 in the present embodiment needs not to be coupled to the external power source through any power line or bonding wire (as in the conventional technique). Accordingly, the volume of the thermoelectric device 100 in the present embodiment is reduced, and the thermoelectric device 100 can be easily integrated into a chip package structure or a chip stack structure. Besides, the power transmission path of the conductive vias 120 in the present embodiment is shorter than that of the power line or bonding wire in the conventional technique. Thus, the thermoelectric device 100 in the present embodiment has lower resistance than a conventional thermoelectric device.

In the present embodiment, the cooling (or heating) effect of the thermoelectric couple module 140 may be affected by the air flow and air return in the external environment. Thus, the thermoelectric device 100 may have a sealant 190 for sealing the thermoelectric couple module 140. The sealant 190 surrounds the thermoelectric couple module 140 and is disposed between the first substrate 110 and the second substrate 130 to form a sealing chamber A. The inside of the sealing chamber A is substantially in a vacuum state.

As described above, the thermoelectric couple module 140 in the sealing chamber A is not affected by the air flow and air return in the external environment therefore has a good cooling (or heating) effect. In addition, the thermoelectric couple module 140 is isolated from the external environment or contamination of subsequent processes by the sealant 190, and the structural strength of the thermoelectric device 100 is increased by the sealant 190. In the present embodiment, the sealant 190 is made of a thermoelectric material, resin, or other sealing materials. The sealant 190 can be formed together with the first thermoelectric pillars 142a or the second thermoelectric pillars 142b if the sealant 190 is made of a thermoelectric material.

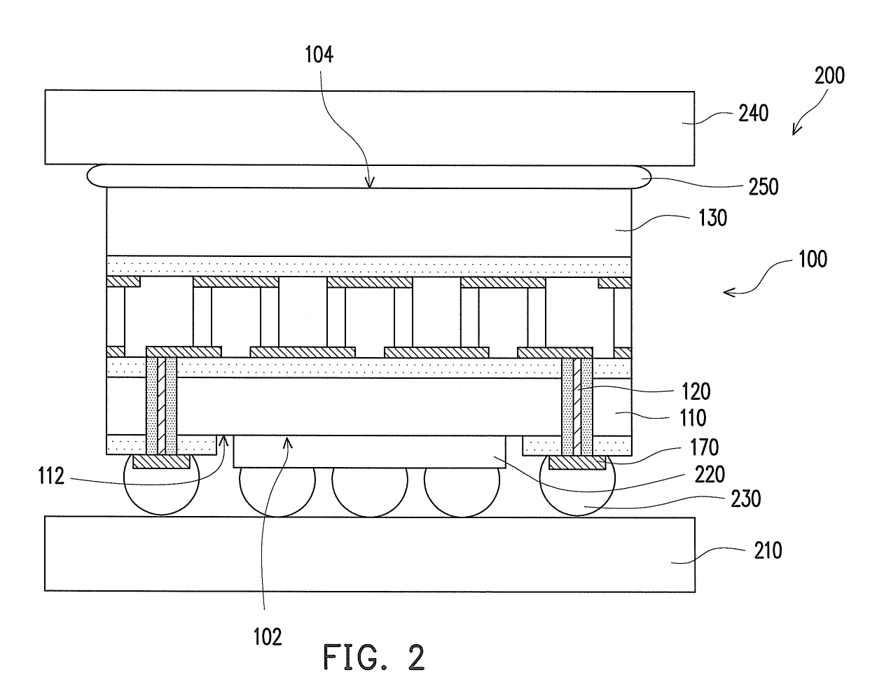

FIG. 2 is a cross-sectional view of a chip package structure according to an embodiment of the disclosure. Referring to FIG. 2, in the present embodiment, the chip package structure 200 includes a carrier substrate 210, a thermoelectric device 100, and a chip 220. The carrier substrate 210 is a single-layer or multilayer circuit board, and the thermoelectric device 100 is disposed on the carrier substrate 210. It should be noted that the thermoelectric device 100 in the present embodiment is the same as the thermoelectric device 100 in the previous embodiment (as shown in FIG. 1). The chip 220 is disposed between the thermoelectric device 100 and the carrier substrate 210, and the chip 220 and the thermoelectric device 100 are respectively coupled to the carrier substrate 210.

In the present embodiment, the chip 220 is disposed on the first surface 112 of the first substrate 110 and exposes the conductive vias 120. The chip 220 and the conductive vias 120 are respectively coupled to the carrier substrate 210 through a plurality of conductive bumps 230. To be specific, the conductive bumps 230 are disposed between the chip 220 and the carrier substrate 210 and between the metal pads 170 and the carrier substrate 210.

In the present embodiment, when the thermoelectric device 100 is coupled to an external power source (not shown) through the conductive vias 120, an end of the thermoelectric device 100 adjacent to the chip 220 is a cold end 102, and an end of the thermoelectric device 100 away from the chip 220 is a hot end 104. Accordingly, the cold end 102 of the thermoelectric device 100 releases the heat generated by the chip 220. In addition, as shown in FIG. 2, the second substrate 130 is located at the hot end 104, and a heat sink 240 may be disposed on the second substrate 130 to improve the heat dissipation efficiency of the hot end 104, wherein the heat sink 240 may be made of a material with high heat conductivity, such as metal.

To be specific, the heat sink 240 is fixed onto the second substrate 130 through an adhesive layer 250, wherein the adhesive layer 250 is disposed between the heat sink 240 and the second substrate 130, and the material thereof includes heat dissipation paste, solder, and any other material with high heat conductivity.

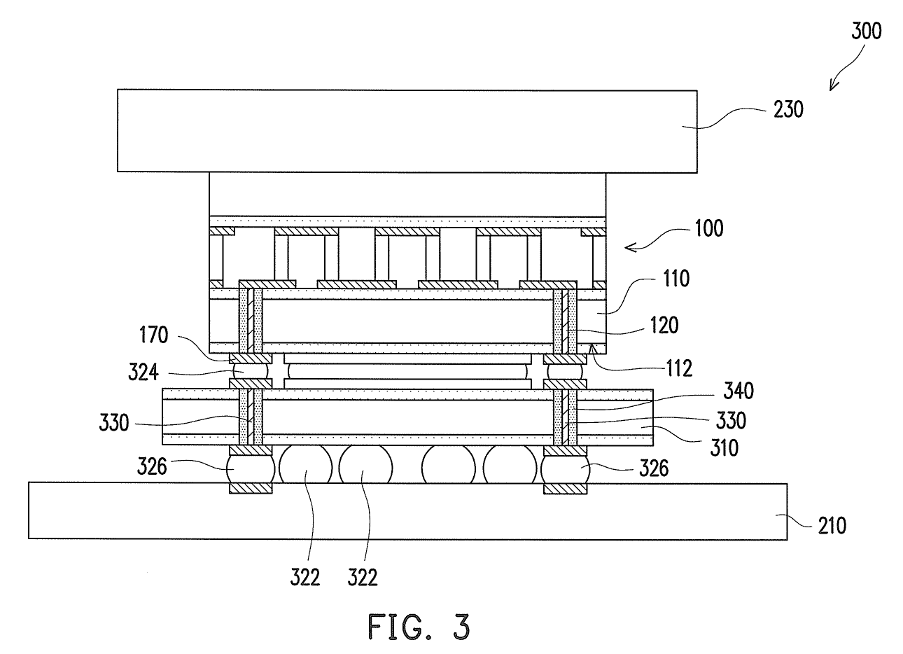

FIG. 3 is a cross-sectional view of a chip package structure according to an embodiment of the disclosure. The chip package structure 300 in the present embodiment is similar to the chip package structure 200 illustrated in FIG. 2. The difference between the two is that in the present embodiment, the chip 310 is disposed on the first surface 112 of the first substrate 110 and covers the conductive vias 120, the chip 310 is coupled to the carrier substrate 210, and the metal pads 170 are coupled to the carrier substrate 210 through the chip 310.

To be specific, the chip 310 is coupled to the carrier substrate 210 through a plurality of conductive bumps 322, wherein the conductive bumps 322 are disposed between the chip 310 and the carrier substrate 210. The metal pads 170 are coupled to a plurality of conductive vias 330 running through the chip 310 through a plurality of conductive bumps 324, and the conductive vias 330 are electrically connected to a plurality of conductive bumps 326 located between the chip 310 and the carrier substrate 210. Besides, in the present embodiment, an insulation material 340 may be disposed between the conductive vias 330 and the chip 310 to avoid short circuit between the conductive vias 330 and the chip 310.

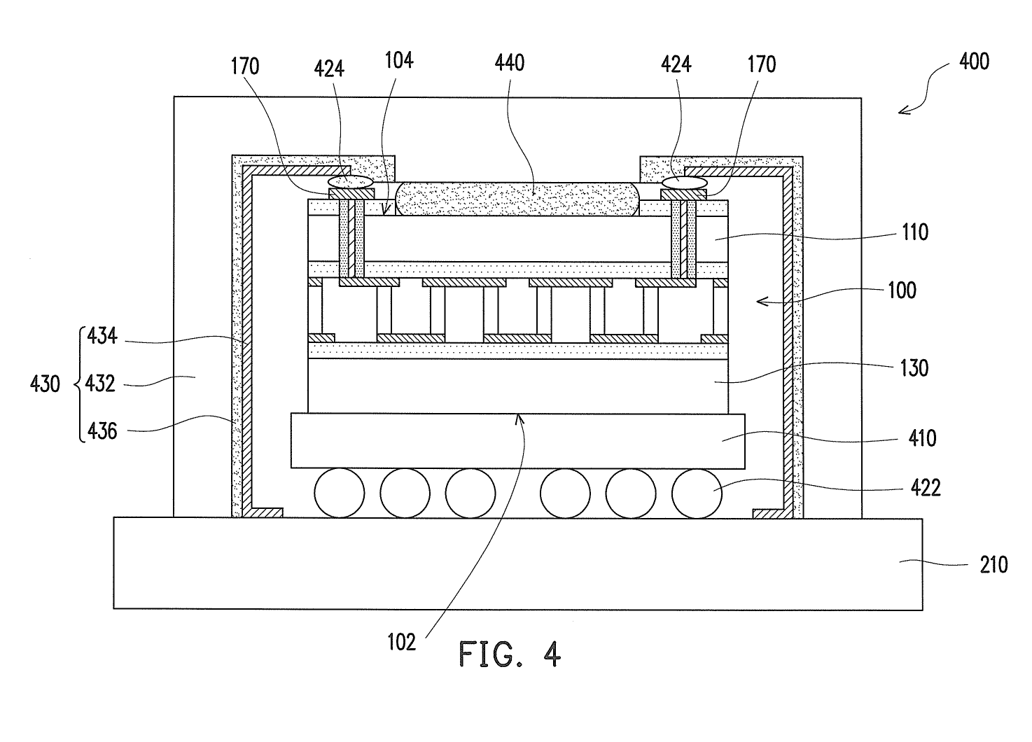

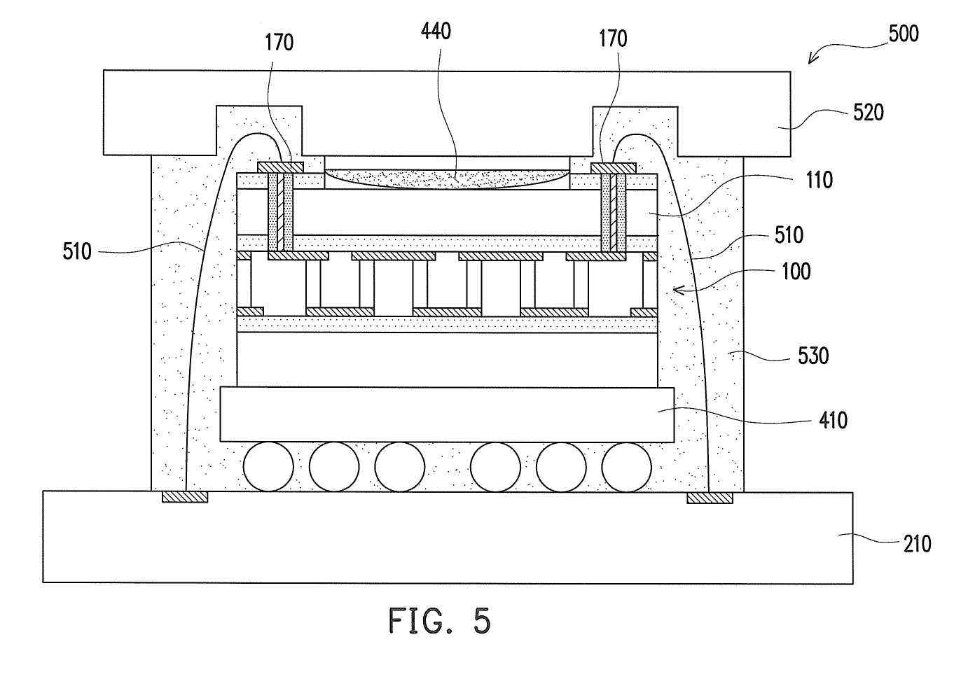

FIG. 4 is a cross-sectional view of a chip package structure according to an embodiment of the disclosure. FIG. 5 is a cross-sectional view of a variation of the chip package structure in FIG. 4.

The chip package structure 400 in the present embodiment is similar to the chip package structure 200 illustrated in FIG. 2, and the major difference between the two is that in the chip package structure 400 of the present embodiment, the chip 410 is disposed on the second substrate 130 and coupled to the carrier substrate 210. To be specific, the chip 410 is coupled to the carrier substrate 210 through a plurality of conductive bumps 422, wherein the conductive bumps 422 are disposed between the chip 410 and the carrier substrate 210.

In the present embodiment, when the thermoelectric device 100 is coupled to an external power source (not shown), an end of the thermoelectric device 100 adjacent to the chip 410 is a cold end 102, and an end of the thermoelectric device 100 away from the chip 410 is a hot end 104. Accordingly, the cold end 102 of the thermoelectric device 100 can release the heat generated by the chip 410.

As shown in FIG. 4, the first substrate 110 is located at the hot end 104, and the chip package structure 400 may have a heat dissipating cover 430 for increasing the heat dissipation efficiency of the hot end 104. To be specific, the heat dissipating cover 430 is disposed on the carrier substrate 210 and covers the thermoelectric device 100 and the chip 410. The heat dissipating cover 430 has a main body 432 and a conductive circuit 434 located in the main body 432. The metal pads 170 on the first substrate 110 are coupled to the conductive circuit 434 through a plurality of conductive bumps 424 and to the carrier substrate 210 through the conductive circuit 434. The conductive bumps 424 are disposed between the metal pads 170 and the conductive circuit 434.

The main body 432 may be made of a material with high heat conductivity, such as metal. It should be noted that when the main body 432 is made of a conductive material (such as metal), an insulation layer 436 is disposed between the main body 432 and the conductive circuit 434 to avoid short circuit between the main body 432 and the conductive circuit 434. In addition, the heat dissipating cover 430 is bonded to the first substrate 110 through an adhesive layer 440, wherein the adhesive layer 440 is disposed between the first substrate 110 and the heat dissipating cover 430, and the adhesive layer 440 is made of a material with high heat conductivity (for example, a heat dissipation paste) or an insulation material (for example, resin).

Referring to FIG. 5, in the present embodiment, the metal pads 170 of the thermoelectric device 100 are coupled to the carrier substrate 210 through a plurality of conductive lines 510. In addition, the chip package structure 500 may have a heat sink 520 disposed on the first substrate 110. In the present embodiment, a molding compound 530 may be disposed between the heat sink 520 and the carrier substrate 210 for encapsulating the thermoelectric device 100, the chip 410, and the conductive lines 510, so as to protect the conductive lines 510.

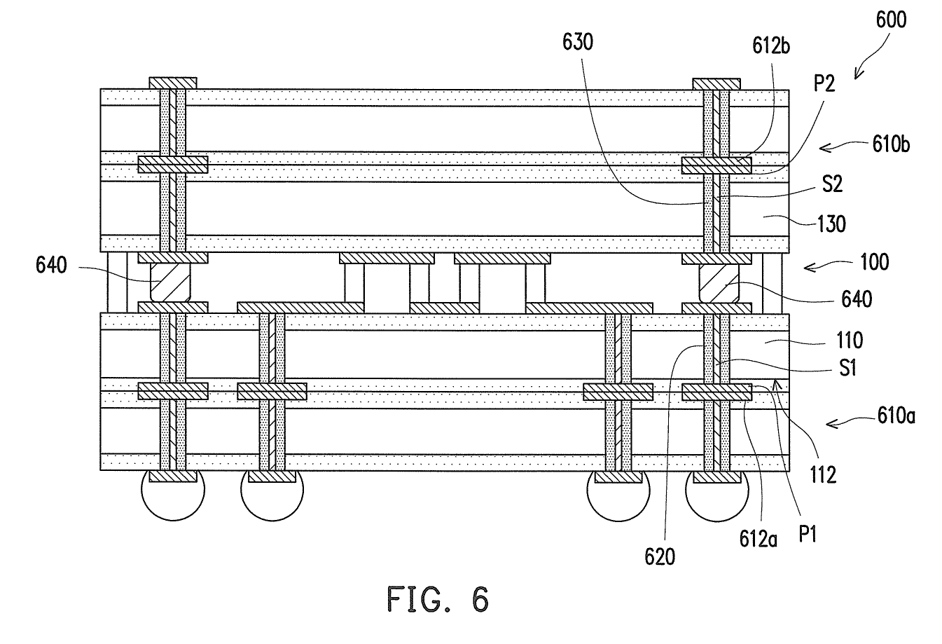

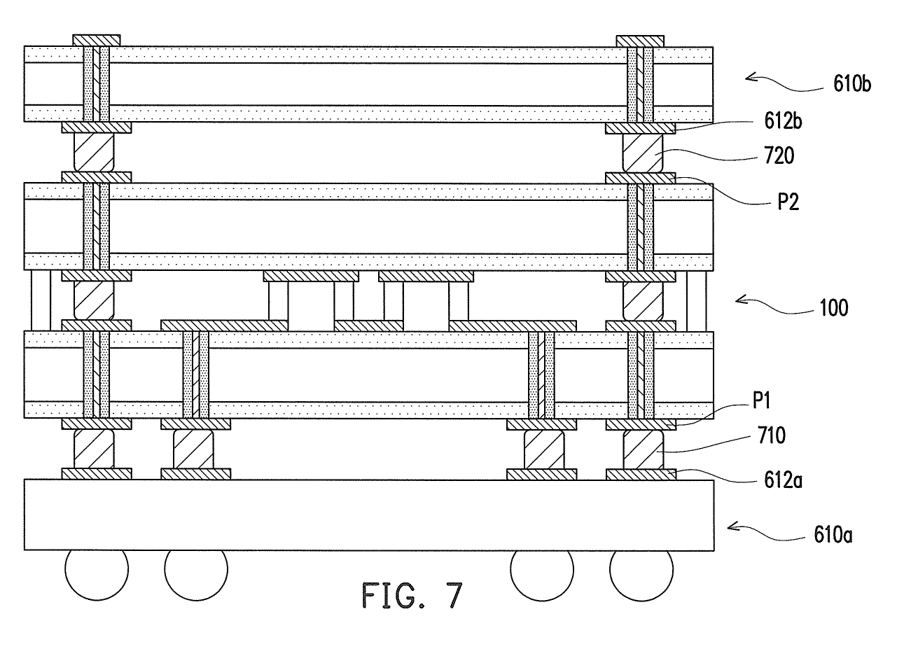

FIG. 6 is a cross-sectional view of a chip stack structure according to an embodiment of the disclosure. FIG. 7 is a cross-sectional view of a variation of the chip stack structure in FIG. 6.

Referring to FIG. 6, in the present embodiment, the chip stack structure 600 includes a plurality of chips 610a and 610b stacked together and a thermoelectric device 100. The thermoelectric device 100 is disposed between any adjacent two of the chips 610a and 610b. Only two chips 610a and 610b are illustrated in FIG. 6 demonstratively; however, the number of the chips is not limited in the disclosure.

In the present embodiment, the chip 610a is coupled to the chip 610b through the thermoelectric device 100. To be specific, the thermoelectric device 100 further includes a plurality of first signal vias S1 running through the first substrate 110, a plurality of second signal vias S2 running through the second substrate 130, and a plurality of conductive bumps 640. The conductive bumps 640 are located between the first substrate 110 and the second substrate 130 and respectively couple the corresponding first signal vias S1 and second signal vias S2. As described above, the chip 610a is coupled to the chip 610b through the first signal vias S1, the conductive bumps 640, and the second signal vias S2.

In addition, an insulation material 620 may be disposed between the first signal vias S1 and the first substrate 110 to avoid short circuit between the first signal vias S1 and the first substrate 110. Similarly, an insulation material 630 may be disposed between the second signal vias S2 and the second substrate 130 to avoid short circuit between the second signal vias S2 and the second substrate 130.

In the present embodiment, the thermoelectric device 100 further includes a plurality of metal pads P1 and P2, wherein the metal pads P1 are disposed on the first surface 112 of the first substrate 110 and are connected to the first signal vias S1. The metal pads P2 are disposed on the second substrate 130 and are connected to the second signal vias S2.

It should be noted that the metal pads P1 are directly connected to a plurality of metal pads 612a of the chip 610a, and the chip 610a is attached to the first substrate 110 of the thermoelectric device 100. Besides, the metal pads P2 are directly connected to a plurality of metal pads 612b of the chip 610b, and the chip 610b is attached to the second substrate 130 of the thermoelectric device 100. In the present embodiment, one of the chips 610a and 610b serves as a calculation chip while the other is only a dummy chip for dissipating heat.

In another embodiment of the disclosure, the metal pads P1 may be coupled to the metal pads 612a of the chip 610a through a plurality of conductive bumps 710, and the metal pads P2 may be coupled to the metal pads 612b of the chip 610b through a plurality of conductive bumps 720 (as shown in FIG. 7).

The method for fabricating the thermoelectric device 100 in FIG. 1 will be described below.

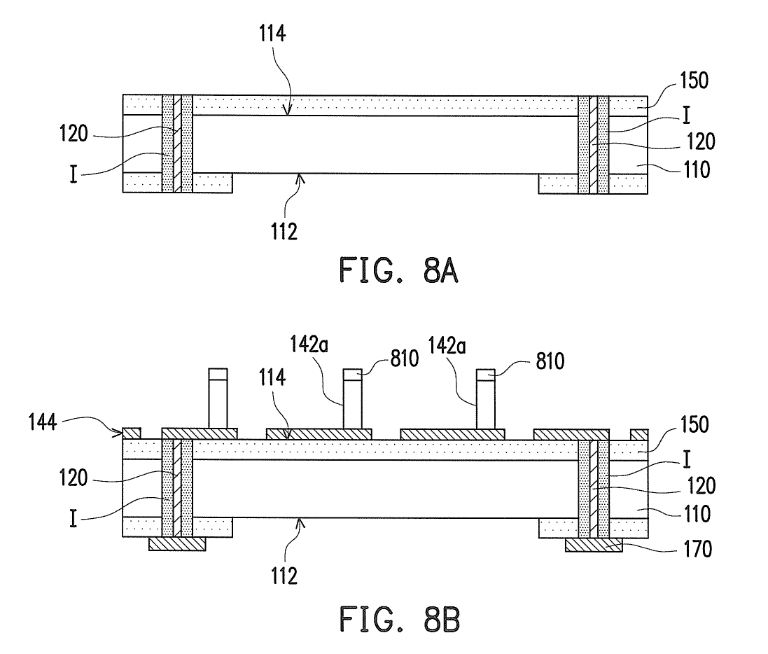

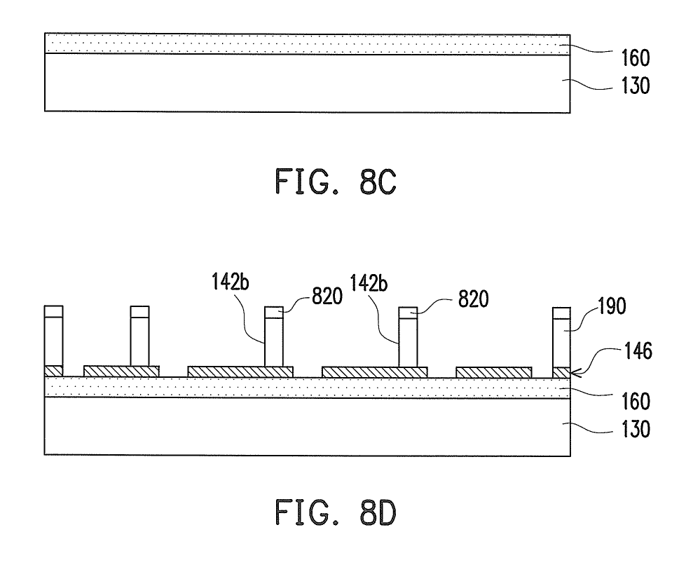

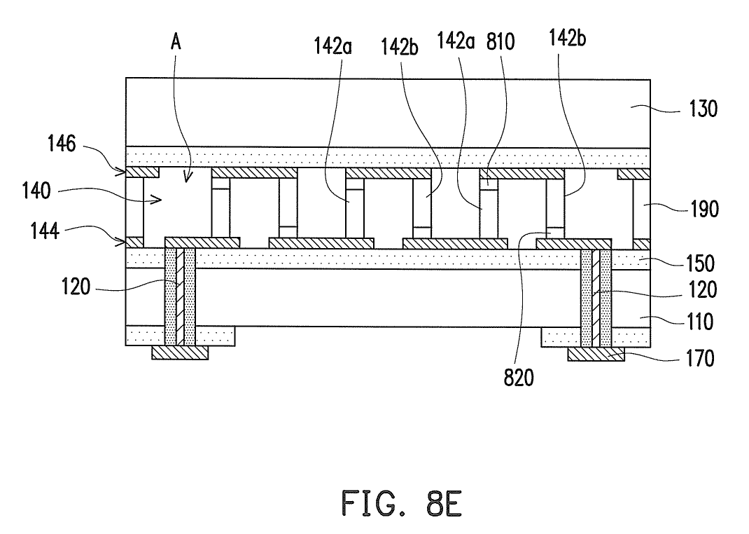

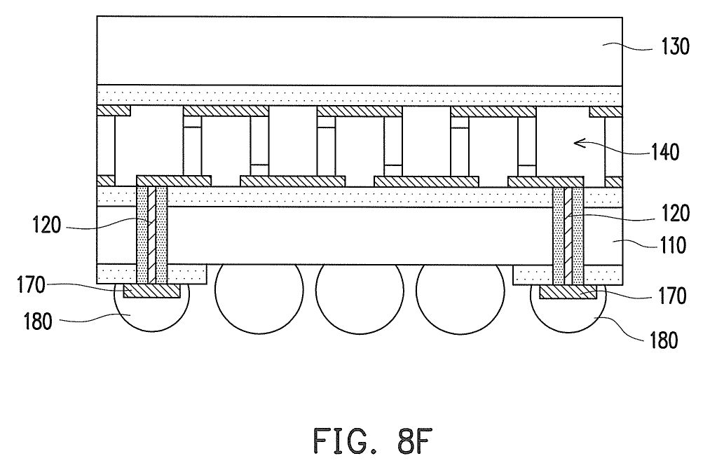

FIGS. 8A˜8F are cross-sectional views illustrating a fabrication process of a thermoelectric device according to an embodiment of the disclosure.

First, referring to FIG. 8A, a first substrate 110, a plurality of conductive vias 120, and a first insulation layer 150 are provided, wherein the first substrate 110 has a first surface 112 and a second surface 114 opposite to the first surface 112. The conductive vias 120 run through the first substrate 110 and respectively connect the first surface 112 and the second surface 114. The first insulation layer 150 is disposed on the second surface 114.

In the present embodiment, the first substrate 110 may be a metal substrate, a silicon substrate, or other suitable substrate, wherein the silicon substrate may be a chip. In addition, in the present embodiment, when the first substrate 110 is a non-insulated substrate (for example, a metal substrate or a silicon substrate), a insulation material I may be formed between the conductive vias 120 and the first substrate 110 to avoid short circuit between the first substrate 110 and the conductive vias 120.

Then, referring to FIG. 8B, a first electrode pattern layer 144 is formed on the first insulation layer 150, wherein the first electrode pattern layer 144 is coupled to the conductive vias 120. In addition, in the present embodiment, a plurality of metal pads 170 may be further formed on the first surface 112 of the first substrate 110, and the metal pads 170 are coupled to the conductive vias 120.

Thereafter, referring to FIG. 8B again, a plurality of first thermoelectric pillars 142a is formed on the first electrode pattern layer 144, and the first thermoelectric pillars 142a are coupled to the first electrode pattern layer 144. The material of the first thermoelectric pillars 142a includes a first type thermoelectric material (for example, an N-type or a P-type semiconductor material). In addition, in the present embodiment, solders 810 may be disposed at the end of the first thermoelectric pillars 142a away from the first insulation layer 150.

Next, referring to FIG. 8C, a second substrate 130 and a second insulation layer 160 are provided, wherein the second insulation layer 160 is disposed on the second substrate 130. Thereafter, referring to FIG. 8D, a second electrode pattern layer 146 is formed on the second insulation layer 160.

After that, referring to FIG. 8D again, a plurality of second thermoelectric pillars 142b is formed on the second electrode pattern layer 146, wherein the second thermoelectric pillars 142b are coupled to the second electrode pattern layer 146. The material of the second thermoelectric pillars 142b includes a second type thermoelectric material (for example, an N-type or a P-type semiconductor material). In addition, in the present embodiment, solders 820 may be disposed at the end of the second thermoelectric pillars 142b away from the second insulation layer 160. Moreover, in the present embodiment, a sealant 190 may be formed on the second insulation layer 160 while forming the second thermoelectric pillars 142b, wherein the sealant 190 surrounds the second thermoelectric pillars 142b. The material of the sealant 190 may be the same as that of the second thermoelectric pillars 142b or resin. In another embodiment of the disclosure, the sealant 190 may also be formed together with the first thermoelectric pillars 142a.

Thereafter, referring to FIG. 8E, the second substrate 130 is disposed on the first substrate 110 to locate the first thermoelectric pillars 142a and the second thermoelectric pillars 142b between the first electrode pattern layer 144 and the second electrode pattern layer 146, wherein the first thermoelectric pillars 142a and the second thermoelectric pillars 142b are connected with each other in series through the first electrode pattern layer 144 and the second electrode pattern layer 146 to form a thermoelectric couple module 140. To be specific, the first thermoelectric pillars 142a may be connected to the second electrode pattern layer 146 through the solders 810, and the second thermoelectric pillars 142b may be connected to the first electrode pattern layer 144 through the solders 820.

Additionally, in the present embodiment, the sealant 190 is also disposed on the first insulation layer 150 when the second substrate 130 is disposed on the first substrate 110. Herein, a sealing chamber A is formed between the sealant 190, the first substrate 110, and the second substrate 130. The sealing chamber A may be formed by disposing the second substrate 130 on the first substrate 110 in a vacuum environment.

After that, referring to FIG. 8F, in the present embodiment, a plurality of conductive bumps 180 is respectively formed on the metal pads 170, wherein the conductive bumps 180 are coupled to the conductive vias 120 through the metal pads 170, and the thermoelectric couple module 140 is coupled to an external power source through these conductive bumps 180.

As described above, in the disclosure, the thermoelectric device is coupled to an external power source through conductive vias. Thus, the thermoelectric device in the disclosure does not need to be coupled to the external power source through any power line or bonding wire (as in the conventional technique). Accordingly, in the disclosure, the volume of the thermoelectric device is reduced, and the thermoelectric device can be easily integrated into a chip package structure or a chip stack structure. In addition, the power transmission path of the conductive vias in the disclosure is shorter than that of the power line or bonding wire in the conventional technique. Thus, the thermoelectric device in the disclosure has lower resistance than a conventional thermoelectric device.

Moreover, in the disclosure, a sealant can seal a thermoelectric couple module into a sealing chamber formed by the first substrate, the second substrate and the sealant so that the thermoelectric couple module will not be affected by the air flow and air return in the external environment, and accordingly, the cooling (or heating) effect of the thermoelectric couple module is improved. Furthermore, the thermoelectric couple module is isolated from the external environment or the contamination in subsequent processes by the sealant, and the structural strength of the thermoelectric device is improved by the sealant.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A thermoelectric device, comprising:
a first substrate, having a first surface and a second surface opposite to the first surface;
a plurality of conductive vias, running through the first substrate and respectively connecting the first surface and the second surface;
a second substrate, disposed opposite to the first substrate, wherein the second surface of the first substrate faces the second substrate;
a thermoelectric couple module, including a plurality of thermoelectric couples connected with each other in series, disposed between the first substrate and the second substrate and coupled to the conductive vias;
a first insulation layer, disposed between the thermoelectric couple module and the first substrate; and
a second insulation layer, disposed between the thermoelectric couple module and the second substrate.

2. The thermoelectric device according to claim 1, wherein the first substrate is a metal substrate or a silicon substrate.

3. The thermoelectric device according to claim 2, wherein the silicon substrate is a chip.

4. The thermoelectric device according to claim 1, wherein the second substrate is a metal substrate or a silicon substrate.

5. The thermoelectric device according to claim 4, wherein the silicon substrate is a chip.

6. The thermoelectric device according to claim 1 further comprising a sealant, wherein the sealant surrounds the thermoelectric couple module and is disposed between the first substrate and the second substrate to form a sealing chamber, an inside of the sealing chamber is substantially in a vacuum state.

7. The thermoelectric device according to claim 1 further comprising:
a plurality of metal pads, wherein the metal pads are disposed on the first surface of the first substrate and are respectively connected to the conductive vias; and
a plurality of conductive bumps disposed on the metal pads.

8. A chip package structure, comprising:
a carrier substrate;
a thermoelectric device, disposed on the carrier substrate, wherein the thermoelectric device comprises:
a first substrate, having a first surface and a second surface opposite to the first surface;
a plurality of conductive vias, running through the first substrate and respectively connecting the first surface and the second surface;
a second substrate, disposed opposite to the first substrate, wherein the second surface of the first substrate faces the second substrate;
a thermoelectric couple module, including a plurality of thermoelectric couples connected with each other in series, disposed between the first substrate and the second substrate and coupled to the conductive vias;
a first insulation layer, disposed between the thermoelectric couple module and the first substrate;
a second insulation layer, disposed between the thermoelectric couple module and the second substrate; and
a chip, disposed between the thermoelectric device and the carrier substrate, wherein the chip and the thermoelectric device are respectively coupled to the carrier substrate; and
a heat sink disposed on the second substrate.

9. The chip package structure according to claim 8, wherein the first substrate is a metal substrate or a silicon substrate.

10. The chip package structure according to claim 9, wherein the silicon substrate is a chip.

11. The chip package structure according to claim 8, wherein the second substrate is a metal substrate or a silicon substrate.

12. The chip package structure according to claim 11, wherein the silicon substrate is a chip.

13. The chip package structure according to claim 8 further comprising a sealant, wherein the sealant surrounds the thermoelectric couple module and is disposed between the first substrate and the second substrate to form a sealing chamber, an inside of the sealing chamber is substantially in a vacuum state.

14. The chip package structure according to claim 8, wherein the chip is disposed on the first surface of the first substrate and exposes the conductive vias, and the chip and the conductive vias are respectively coupled to the carrier substrate, a plurality of conductive bumps disposed between the chip and the carrier substrate and between the metal pads and the carrier substrate.

15. The chip package structure according to claim 8, wherein the chip is disposed on the first surface of the first substrate and covers the conductive vias, the chip is coupled to the carrier substrate, and the metal pads are coupled to the carrier substrate through the chip.

16. The chip package structure according to claim 8 further comprising a plurality of conductive bumps disposed between the chip and the carrier substrate and between the metal pads and the chip.

17. The chip package structure according to claim 8, wherein the chip is disposed on the second substrate and is coupled to the carrier substrate.

18. The chip package structure according to claim 17 further comprising a plurality of conductive bumps disposed between the chip and the carrier substrate.

19. The chip package structure according to claim 17 further comprising a heat dissipating cover, wherein the heat dissipating cover is disposed on the carrier substrate and covers the thermoelectric device and the chip, the heat dissipating cover has a conductive circuit, and the metal pads on the first substrate are coupled to the conductive circuit and to the carrier substrate through the conductive circuit.

20. The chip package structure according to claim 17 further comprising:
a heat sink, disposed on the first substrate; and
a plurality of conductive lines, coupled between the metal pads and the carrier substrate.

21. The chip package structure according to claim 20 further comprising a molding compound, wherein the molding compound is disposed between the heat sink and the carrier substrate and encapsulates the thermoelectric device, the chip, and the conductive lines.

22. A chip stack structure, comprising:
a plurality of chips, stacked together;
a thermoelectric device, disposed between any adjacent two of the chips, the thermoelectric device comprising:
a first substrate, having a first surface and a second surface opposite to the first surface;
a plurality of conductive vias, running through the first substrate and respectively connecting the first surface and the second surface;
a second substrate, disposed opposite to the first substrate, wherein the second surface of the first substrate faces the second substrate;
a thermoelectric couple module, including a plurality of thermoelectric couples connected with each other in series, disposed between the first substrate and the second substrate and coupled to the adjacent chip through the conductive vias;
a first insulation layer, disposed between the thermoelectric couple module and the first substrate; and
a second insulation layer, disposed between the thermoelectric couple module and the second substrate.

23. The chip stack structure according to claim 22, wherein the first substrate is a chip.

24. The chip stack structure according to claim 22, wherein the second substrate is a chip.

25. The chip stack structure according to claim 22 further comprising a sealant, wherein the sealant surrounds the thermoelectric couple module and is disposed between the first substrate and the second substrate to form a sealing chamber, an inside of the sealing chamber is substantially in a vacuum state.

26. The chip stack structure according to claim 22 further comprising a plurality of first signal vias running through the first substrate, a plurality of second signal vias running through the second substrate, and a plurality of conductive bumps, wherein each of the conductive bumps is located between the first substrate and the second substrate and respectively couple the corresponding first signal via and the corresponding second signal via, the two chips adjacent to opposite two sides of the thermoelectric device are coupled with each other through the first signal vias, the conductive bumps, and the second signal vias.

27. A fabrication method of a thermoelectric device, comprising:
providing a first substrate, a plurality of conductive vias, and a first insulation layer, wherein the first substrate has a first surface and a second surface opposite to the first surface, the conductive vias run through the first substrate and respectively connect the first surface and the second surface, and the first insulation layer is disposed on the second surface;
forming a first electrode pattern layer on the first insulation layer, wherein the first electrode pattern layer is coupled to the conductive vias;
forming a plurality of first thermoelectric pillars on the first electrode pattern layer, wherein the first thermoelectric pillars are coupled to the first electrode pattern layer, and a material of the first thermoelectric pillars comprises a first type thermoelectric material;
providing a second substrate and a second insulation layer, wherein the second insulation layer is disposed on the second substrate;
forming a second electrode pattern layer on the second insulation layer;
forming a plurality of second thermoelectric pillars on the second electrode pattern layer, wherein the second thermoelectric pillars are coupled to the second electrode pattern layer, and a material of the second thermoelectric pillars comprises a second type thermoelectric material; and
disposing the second substrate on the first substrate to locate the first thermoelectric pillars and the second thermoelectric pillars between the first electrode pattern layer and the second electrode pattern layer, wherein the first thermoelectric pillars and the second thermoelectric pillars are connected with each other in series through the first electrode pattern layer and the second electrode pattern layer to form a thermoelectric couple module.

28. The fabrication method according to claim 27 further comprising forming a sealant between the first substrate and the second substrate, wherein the sealant surrounds the first thermoelectric pillars and the second thermoelectric pillars, and a sealing chamber is formed between the sealant, the first substrate, and the second substrate in a vacuum environment.

29. The fabrication method according to claim 27 further comprising forming a plurality of conductive bumps on the first surface, wherein the conductive bumps are respectively coupled to the conductive vias.
